(19) United States
(12) Patent Application Publication
(10) Pub. No.: US 2010/0186808 A1
(43) Pub. Date: Jul. 29, 2010

(54) PLATING THROUGH TUNNEL DIELECTRICS FOR SOLAR CELL CONTACT FORMATION

(76) Inventor: PETER BORDEN, San Mateo, CA (US)

Correspondence Address: APPLIED MATERIALS;C/O PILLSBURY WINTHROP, SHAW and PITTMAN LLP, P.O. Box 10500, McLean, VA, 22120, US

(21) Appl. No.: 12/360,809

(22) Filed: Jan. 27, 2009

(51) Int. Cl. H01L 31/0256; H01L 31/18

(52) U.S. Cl. 136/256; 438/98; 257/E31.003

(57) ABSTRACT

In general, the present invention relates to forming electrical contacts in a semiconductor device, including contact regions in solar cells. According to certain aspects, the invention provides methods and apparatuses for forming plated contacts in the presence of a thin tunnel oxide. Preferably, the tunnel oxide dielectric layer is thin enough to sustain a tunnel current. Plating over the tunnel dielectric is then performed. The benefits of the invention include that no annealing is required to form the metal-silicide contact. Moreover, there is no requirement for special metals for n- or p-type contacts. Another advantage is that shallow contacts according to the invention avoid punching through a shallow junction, thereby enabling the use of shallower emitters with improved blue response. Still further, there is no need to control the amount of silicide metal plated in order to prevent driving the silicide alloy through the junction.

### CROSS REFERENCE TO RELATED APPLICATIONS

### Field of the Invention

The present invention relates to forming electrical contacts in a semiconductor device, and more particularly to methods and apparatuses for plating through tunnel oxides to metallize contact regions in solar cells.

### BACKGROUND

Plating is a known method to selectively metallize contact regions, including contact regions for solar cells. FIG. 1 shows a prior art plated contact. As shown in FIG. 1, in a conventional process, a dielectric layer 106 such as a nitride or oxide, is laid down on the silicon surface. The silicon has a p-n junction, for example a shallow n-type region 108 over a low doped p-type substrate 110. Contact holes are opened in the dielectric 106 by etching, for example. A metal 102 such as nickel is then selectively plated in these contact holes. For example, a seed material is deposited by electroless plating and then the metal is plated on the seed material. More particularly, the seed selectively deposits only where the semiconductor is exposed via the contact holes, and the plating only happens on a conductive surface, which is the seed layer, but not on the dielectric.

Many problems exist with the prior art approaches and techniques. For example, the nickel must be relatively thick in many cases to act as a diffusion barrier should a subsequent layer of copper be plated over the nickel, for example. Accordingly, the wafer must then be carefully alloyed to form a nickel-silicide contact. However, care must be taken, lest the contact alloy too deep and short out the p-n junction.

Accordingly, there remains a need in the art for improved plated contacts and contact regions, including for use with solar cells.

### SUMMARY

In general, the present invention relates to forming electrical contacts in a semiconductor device, including contact regions in solar cells. According to certain aspects, the invention provides methods and apparatuses for forming plated contacts in the presence of a thin tunnel oxide. Preferably, the tunnel oxide dielectric layer is thin enough to sustain a tunnel current. Plating over the tunnel dielectric is then performed. The benefits of the invention include that no annealing is required to form the metal-silicide contact. Moreover, there is no requirement for special metals for n- or p-type contacts. Another advantage is that shallow contacts according to the invention avoid punching through a shallow junction, thereby enabling the use of shallower emitters with improved blue response. Still further, there is no need to control the amount of silicide metal plated in order to prevent driving the silicide alloy through the junction.

In furtherance of these and other aspects, a method of forming a contact in a solar cell having a p-n junction according to embodiments of the invention includes creating one or more contact regions over the p-n junction; forming a tunnel dielectric in the one or more contact regions, wherein the forming step includes forming the tunnel dielectric thin enough to sustain a tunnel current therethrough; and plating a metal over the tunnel dielectric material to form the contact.

In additional furtherance of these and other aspects, a solar cell according to embodiments of the invention comprises a p-n junction; one or more contact regions formed over the p-n junction; a tunnel dielectric formed in the one or more contact regions, wherein the tunnel dielectric is thin enough to sustain a tunnel current therethrough; and a metal plated over the tunnel dielectric material to form a contact to the p-n junction.

### BRIEF DESCRIPTION OF THE DRAWINGS

These and other aspects and features of the present invention will become apparent to those ordinarily skilled in the art upon review of the following description of specific embodiments of the invention in conjunction with the accompanying figures, wherein:

FIG. 1 shows a prior art plated contact;

FIG. 2 shows an improved contact according to embodiments of the invention; and

FIG. 3 shows a process flow according to embodiments of the invention.

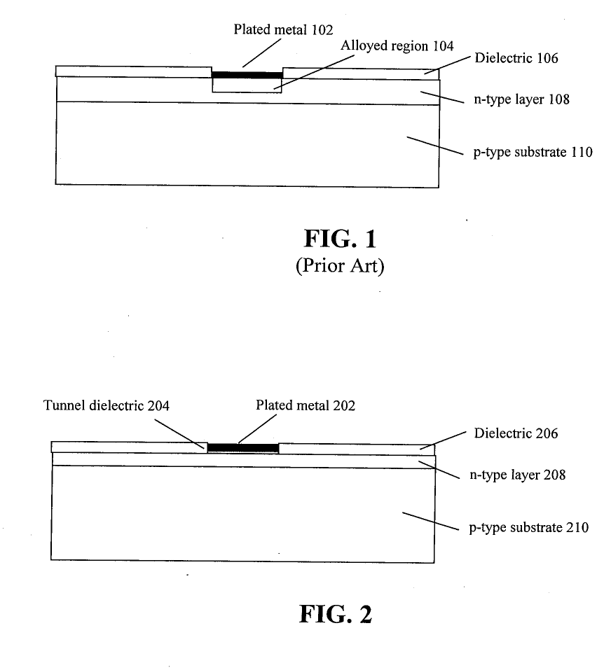

### DETAILED DESCRIPTION

The present invention will now be described in detail with reference to the drawings, which are provided as illustrative examples of the invention so as to enable those skilled in the art to practice the invention. Notably, the figures and examples below are not meant to limit the scope of the present invention to a single embodiment, but other embodiments are possible by way of interchange of some or all of the described or illustrated elements. Moreover, where certain elements of the present invention can be partially or fully implemented using known components, only those portions of such known components that are necessary for an understanding of the present invention will be described, and detailed descriptions of other portions of such known components will be omitted so as not to obscure the invention. In the present specification, an embodiment showing a singular component should not be considered limiting; rather, the invention is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present invention encompasses present and future known equivalents to the known components referred to herein by way of illustration.

In general, the present invention relates to forming plated contacts in the presence of a thin tunnel oxide. According to certain aspects, the present inventors recognize that a thin oxide underneath a contact can improve contact properties and eliminate the need for alloying the contact.

Accordingly, in the present invention, a thin tunnel dielectric is formed before plating. FIG. 2 shows an improved contact according to the invention. As shown in FIG. 2, similar to a conventional process, a dielectric layer 206 such as a nitride or oxide, is laid down on a substrate surface. The substrate has a p-n junction, for example a shallow n-type region 208 over a p-type substrate 210. Contact holes are opened in the dielectric 206. In contrast to the prior art, a tunnel dielectric 204 is provided in the contact region, and then a plated contact 202 is formed on the tunnel dielectric 204.

In embodiments, substrate 210 is comprised of silicon, and is low-doped with p-type impurities. Many other substrate materials can be used and this and many other methods for obtaining a desired polarity concentration and type are possible, as will be appreciated by those skilled in the art. Shallow n-type region 208 is preferred because shallow emitters provide improved blue response. In such a case, the n-type region 208 may be approximately 0.3-0.5 microns thick at the surface of the substrate 210. Moreover, as will be described in more detail below, one advantage of forming the tunnel oxide according to embodiments of the invention is that an alloying step is not necessary, which alleviates the potential problem of the plated contact punching through the shallow p-n junction. However, shallow emitters are not necessary for the invention.

It should be noted that the term contact hole should be construed broadly so as to relate to many types of openings through dielectric layer 206 and many types of solar cell contacts. For example, the holes can provide for point contacts having an area of only a few square microns or millimeters (e.g. having a diameter from about 2 μm to up to 100-200 μm), or they can provide for line contacts that span many centimeters or more, and having widths about 2 to 100 μm. Those skilled in the art of solar cell contacts will appreciate how the teachings of the invention can be applied to these and other various types of contacts and openings.

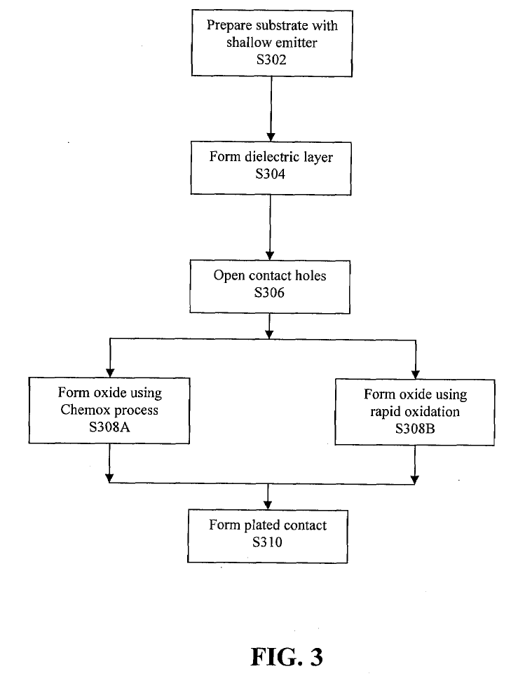

An example process flow according to embodiments of the invention is described more particularly in connection with FIG. 3.

In step S302, a substrate with a p-n junction is prepared or obtained. As set forth above, according to aspects of the invention, a silicon substrate with a shallow emitter is used. Details of its fabrication are not necessary for an understanding of the present invention. Next, in step S304, a dielectric layer is formed on the substrate surface. For example, a nitride such as a silicon nitride with an index of refraction of about 2.1 and thickness of about 76 nm or a stoichiometric oxide such as SiO₂ with thickness about 100 nm is laid down by CVD deposition for nitride or oxide, or thermal oxidation for oxide. A stack could also be used, with a 5 nm SiO₂ formed with rapid thermal oxidation and a 70 nm SiNₓ over the oxide (SiNₓ refers to a material that may not have the standard Si₃N₄ stochiometry of silicon nitride).

Next, in step S306, contact holes are opened in the dielectric layer. This opening step may be done by etching, laser ablation, or any other method that provides a suitable opening the dielectric to expose the underlying substrate such as silicon. More particularly, as set forth above, the type of opening and its dimensions can depend on the particular solar cell contact application such as point contacts and other types of contacts. Those skilled in the art will be able to understand how to form suitable openings for such various types of contacts using various conventional and proprietary methods. Methods might include laser ablation or patterning and etching, or local deposition of an etchant.

Next, in step S308, a thin tunnel dielectric is then formed, using either a wet process (step S308A) or a dry process (step S308B). A dry process can include oxidation in a furnace tube or in a rapid thermal annealer. One wet process, called Chemox (developed at IMEC) forms a thin oxide in an ozonated hydrogen peroxide bath. A wet process (step S308A) such as Chemox is preferred because it is a process step that immediately precedes plating, which is typically another wet processing step. Therefore, both can be done in the same wet tool without additional wafer handling or loading. However, this is not necessary for the invention.

In some embodiments, it is important for the dielectric to be thin enough to carry sufficient current without creating a series impedance. Layers in the 8 to 12 Å range are readily formed using rapid thermal oxidation. Chemox layers are on the order of 8 Å thick. Such thin layers should readily pass current densities consistent with the requirements of a solar cell operating at one sun.

Next, in step S310, the contact metal is plated. In the preferred embodiment, nickel is used, although other metals such as silver, tungsten or copper may also be used. A conventional process for plating including a seed material can be used as described above. Those skilled in the art will understand many alternatives, however.

According to aspects of the invention, in contrast to the prior art plating process, no annealing or alloying process is required. Moreover, there is no requirement for special metals for n- or p-type contacts, such as, for direct contacts, Al contacts p-type and Ag contacts n-type. In this case, contacting to reasonably high doped (mid to high 10¹⁹ doping can be done with any metal, although some may provide better contacts that others by virtue of differing work functions. Still further, there is no need to carefully control the amount of silicide metal plated in order to prevent driving the silicide alloy through the junction as is required in the prior art. Accordingly, plating thicknesses down to about 2 μm can be used, for example.

In any event, to do the plating in step S310, it is necessary to create a potential across the tunnel dielectric, so that electrons can tunnel through the dielectric to reduce metal ions. There are two ways to accomplish this, as will be appreciated by those skilled in the art. For example, one is to place an electrical bias between the solution and the back contact. This must be done in constant current mode, as it will reverse bias the junction and carries the risk of damaging the cell. Another technique is the well known method of light induced plating. The sample is illuminated, causing a photocurrent to flow through the tunnel dielectric. Those skilled in the art will be able to understand such conventional techniques to the overall process flow of the present invention.

Although the present invention has been particularly described with reference to the preferred embodiments thereof, it should be readily apparent to those of ordinary skill in the art that changes and modifications in the form and details may be made without departing from the spirit and scope of the invention. It is intended that the appended claims encompass such changes and modifications.

What is claimed is:

1. A method of forming a contact in a solar cell having a p-n junction, comprising:
creating one or more contact regions over the p-n junction;
forming a tunnel dielectric in the one or more contact regions, wherein the forming step includes forming the tunnel dielectric thin enough to sustain a tunnel current therethrough; and
plating a metal over the tunnel dielectric material to form the contact.

2. A method according to claim 1 wherein the step of forming the tunnel dielectric includes forming an oxide layer using a Chemox process.

3. A method according to claim 1 wherein the step of forming the tunnel dielectric includes forming an oxide layer using thermal oxidation.

4. A method according to claim 1 wherein the metal includes nickel.

5. A method according to claim 1 wherein the metal includes copper.

6. A method according to claim 1 wherein the plating step includes creating a potential across the tunnel dielectric using a light bias to induce a photocurrent.

7. A method according to claim 1 wherein the plating step includes creating a potential across the tunnel dielectric using an electrical bias.

8. A method according to claim 1, wherein the step of forming the tunnel dielectric includes forming a nitride layer.

9. A method according to claim 1, wherein the p-n junction comprises a silicon substrate doped with impurities of a first polarity, and an emitter region near a surface of the substrate with a second polarity opposite the first polarity.

10. A method according to claim 9, wherein the emitter region comprises a shallow emitter.

11. A solar cell, comprising:
a p-n junction;
one or more contact regions formed over the p-n junction;
a tunnel dielectric formed in the one or more contact regions, wherein the tunnel dielectric is thin enough to sustain a tunnel current therethrough; and
a metal plated over the tunnel dielectric material to form a contact to the p-n junction.

12. A solar cell according to claim 12 wherein the tunnel dielectric comprises an oxide layer.

13. A solar cell according to claim 12 wherein the metal includes one or more of nickel and copper.

14. A solar cell according to claim 12, wherein the tunnel dielectric comprises a nitride layer.

15. A solar cell according to claim 12, wherein the p-n junction comprises a silicon substrate doped with impurities of a first polarity, and a shallow emitter region near a surface of the substrate with a second polarity opposite the first polarity.
